(19) United States
(12) Patent Application Publication
(10) Pub. No.: US 2026/0354175 A1
(43) Pub. Date: Nov. 5, 2026

(54) INTEGRATED CIRCUIT PACKAGES AND METHODS

(71) Applicant: Taiwan Semiconductor Manufacturing Co., Ltd., Hsinchu (TW)

(72) Inventors: Yu-Jen Lien, Tainan City (TW); Cheng-Chieh Hsieh, Tainan (TW); Chen-Hua Yu, Hsinchu (TW); Ke-Han Shen, Chiayi City (TW); Hung-Yi Kuo, Taipei City (TW)

(21) Appl. No.: 19/740,723

(22) Filed: Jul. 14, 2026

Related U.S. Application Data
(62) Division of application No. 18/396,903, filed on Dec. 27, 2023.

(51) Int. Cl. H10W 40/22; H10W 70/685; H10W 90/00; H10W 72/20; H10W 72/90

(52) U.S. Cl. CPC H10W 40/226; H10W 70/685; H10W 90/00; H10W 90/701; H10W 72/244; H10W 72/9226; H10W 72/923; H10W 72/942

(57) ABSTRACT

An integrated circuit package and the method of forming the same are provided. The integrated circuit package may comprise a substrate, a first package component bonded to the substrate and a first cooling system over the first package component. The first package component may comprise a first semiconductor die. The first cooling system may comprise a first base over the first package component, wherein the first base may comprise a first recess, a first pin protruding from a bottom of the first recess, and a first raised portion encircling the recess in a top-down view; a lid over the first base, wherein the lid may be spaced apart from the first pin; and a sealant connecting the lid to the first raised portion of the first base.

### CROSS-REFERENCE TO RELATED APPLICATIONS

This application is a divisional of U.S. Patent Application No. 18/396,903 filed on Dec. 27, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4A, 4B, 4C, 4D, 5, 6A, 6B, 7, 8A, 8B, and 8C, illustrate cross-sectional views and top-down views of intermediate stages in the formation of an integrated circuit package with a cooling system, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated circuit package with a cooling system, and a method of forming the same are provided. In accordance with some embodiments, the integrated circuit package comprises one or more integrated circuit die components and the cooling system over the one or more integrated circuit die components. A lower portion of the cooling system may be formed of a material with a high thermal conductivity and may comprise enclosed compartments with pins protruding from bottoms of the enclosed compartments over each of the one or more integrated circuit die components. An upper portion of the cooling system may be sealed to the lower portion of the cooling system and comprise a coolant distribution network. Each of the one or more integrated circuit die components may comprise integrated circuit dies or stacks of integrated circuit dies. The heat generated by the integrated circuit dies or the stacks of the integrated circuit dies may be effectively transferred to a liquid coolant flowing through the cooling system directed by the coolant distribution network. As a result, the one or more integrated circuit die components may be effectively cooled during the operation of the integrated circuit package, thereby improving the performance and reliability of the integrated circuit package.

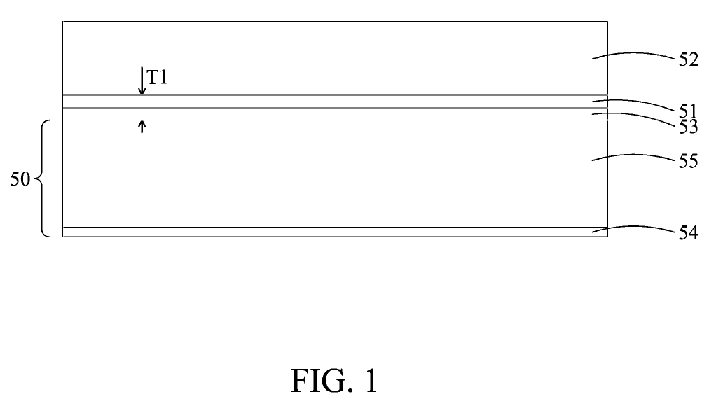

FIGS. 1 through 8C illustrate various intermediate stages of manufacturing an integrated circuit package with an embodiment cooling system. Although FIGS. 1 through 8C illustrate a particular type of package, it should be understood that various embodiment cooling systems may be attached to other types of semiconductor packages as well. In FIG. 1, a material layer 52 is bonded to an integrated circuit die layer 50 by a first bonding layer 51 and a second bonding layer 53. The integrated circuit die layer 50 may comprise a device layer 55 and an isolation layer 54. The isolation layer 54 may be on a first side of the device layer 55 and the second bonding layer 53 may be on a second side of the device layer 55, opposite to the first side.

The device layer 55 may comprise devices (not separately illustrated) and conductive features (not separately illustrated). For example, the device layer 55 may include one or more layers of active devices (e.g., transistors, or the like) that are formed on one or more semiconductor substrates. Conductive features in interconnect structure(s) may be used to electrically connect the active devices together to form functional circuits. The integrated circuit die layer 50 may be singulated into the integrated circuit die components, which may comprise the integrated circuit dies or the stacks of the integrated circuit dies, in a subsequent singulation process, as described in greater details below. The material layer 52 may be subsequently patterned and singulated to form the cooling system over the integrated circuit die components, as also described in greater details below. The material layer 52 may comprise a material with a high thermal conductivity, such as silicon, silicon carbide, chemical vapor deposition (CVD) diamond (e.g., synthetic diamond), or the like, which may result in effective cooling of the subsequently formed integrated circuit die components by the subsequently formed cooling system. In some embodiments, the isolation layer 54 comprises polybenzoxazole (PBO), polyimide (PI), benzocyclobutene (BCB), or the like, and is formed by a suitable coating process, such as spin coating, lamination, or the like. In some embodiments, the isolation layer 54 comprises silicon dioxide, silicon nitride, or the like, and is formed by a suitable deposition process, such as CVD, atomic layer deposition (ALD), or the like.

Prior to the bonding process, the first bonding layer 51 may be formed on the material layer 52 and the second bonding layer 53 may be formed on the integrated circuit die layer 50. The first bonding layer 51 and the second bonding layer 53 may be formed by a suitable deposition process, such as CVD, ALD, or the like. The first bonding layer 51 and the second bonding layer 53 may each comprise an oxide, such as silicon oxide, phosphosilicate glass (PSG), borosilicate glass (BSG), boron-doped phosphosilicate glass (BPSG), a tetraethyl orthosilicate (TEOS) based oxide, or the like; a nitride, such as silicon nitride or the like; or the like. The first bonding layer 51 and the second bonding layer 53 may comprise a same material or different materials. An activation process (e.g., a plasma process, a wet clean, combinations thereof, or the like) may be applied to one or more of the first bonding layer 51 or the second bonding layer 53. For example, the plasma process may form hydroxyl groups on surfaces of the first bonding layer 51 and/or the second bonding layer 53 in preparation of subsequent bonding processes.

During the bonding process the material layer 52 (with the first bonding layer 51) may be placed on the second bonding layer 53 over the integrated circuit die layer 50 using a pick-and-place process or the like, wherein the first bonding layer 51 may be brought into contact with the second bonding layer 53. Then a small pressing force may be applied to press the material layer 52 against the integrated circuit die layer 50 at room temperature. Direct bonds such as dielectric-to-dielectric bonds may be formed between the first bonding layer 51 and the second bonding layer 53. The bonding strength between the first bonding layer 51 and the second bonding layer 53 may be then improved in a subsequent annealing process at a higher temperature. After the bonding process, a total thickness T1 of the first bonding layer 51 and the second bonding layer 53 may be smaller than about 100 nm, which may lead to more effective heat transfer from the subsequently formed integrated circuit die components, which may comprise the integrated circuit dies or the stacks of the integrated circuit dies, to the subsequently formed cooling system, as described in greater details below.

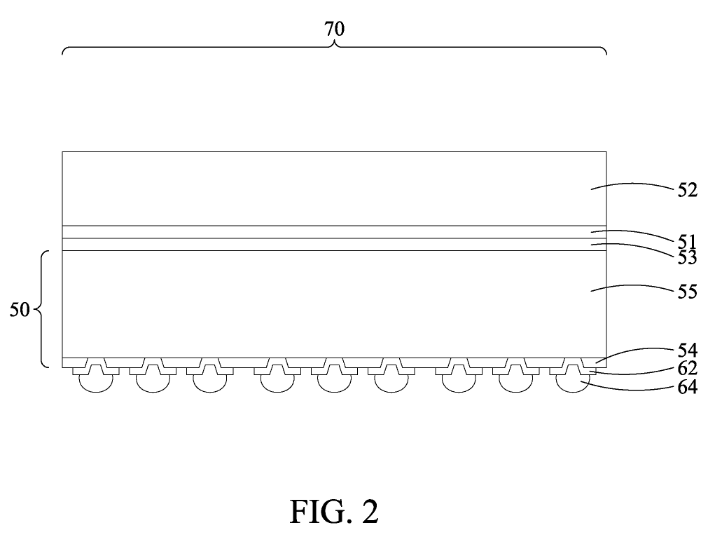

In FIG. 2, under-bump metallizations (UBMs) 62 and electrical connectors 64 are formed. The UBMs 62 may have portions extending along a surface of the isolation layer 54 and portions extending through the isolation layer 54 to physically and electrically couple to the conductive features (not separately illustrated) in the device layer 55. The electrical connectors 64 may be formed on the UBMs 62. As a result, the UBMs 62 and the electrical connectors 64 may be electrically coupled to the devices (not separately illustrated) in the device layer 55. The structure shown in FIG. 2 may be referred to as a first integrated circuit package structure 70.

As an example of forming the UBMs 62, the isolation layer 54 may be patterned to form openings exposing the underlying conductive features in the device layer 55. The patterning may be done by a suitable photolithography and etching processes, such as forming a mask then performing an anisotropic etching. The mask may be removed after the patterning. A seed layer (not separately illustrated) may be formed on the isolation layer 54, in the openings through the isolation layer 54, and on the exposed conductive features in the device layer 55. The seed layer may be a metal layer, which may be a single layer or a composite layer comprising a plurality of sub-layers formed of different materials. In some embodiments, the seed layer comprises a titanium layer and a copper layer over the titanium layer. The seed layer may be formed using a suitable deposition process, such as physical vapor deposition (PVD) or the like. A photoresist may be then formed and patterned on the seed layer. The photoresist may be formed by spin coating or the like and may be exposed to light for patterning. The patterning may form openings through the photoresist to expose the seed layer. The openings may correspond to the UBMs 62.

A conductive material may be formed in the openings of the photoresist and on the exposed portions of the seed layer. The conductive material may be formed by plating, such as electroless plating, electroplating, or the like. The conductive material may comprise a metal or a metal alloy, such as copper, titanium, tungsten, aluminum, the like, or combinations thereof. Then the photoresist and portions of the seed layer on which the conductive material is not formed may be removed. The photoresist may be removed by an acceptable ashing or stripping process, such as using oxygen plasma or the like. Once the photoresist is removed, portions of the seed layer on which the conductive material is not formed may be removed by an acceptable etching process, such as by wet or dry etching. The remaining portions of the seed layer and conductive material may be referred to as the UBMs 62.

Electrical connectors 64 may be then formed on the UBMs 62. The electrical connectors 64 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the electrical connectors 64 comprise a conductive material, such as solder, copper, aluminum, gold, nickel, silver, palladium, tin, the like, or a combination thereof. In such embodiments, the electrical connectors 64 may be formed by initially forming a layer of the conductive material on the UBMs 62 through evaporation, electroplating, printing, solder transfer, ball placement, or the like. Once the layer of the conductive material has been formed on the UBMs 62, a reflow may be performed to shape the layer of the conductive material into the desired bump shapes. In some embodiments, the electrical connectors 64 comprise metal pillars, such as a copper pillar, formed by a sputtering, printing, electroplating, electroless plating, PVD, CVD, or the like, which are solder-free and have substantially vertical sidewalls. A metal cap layer may be formed on top of the metal pillars. The metal cap layer may include nickel, tin, tin-lead, gold, silver, palladium, indium, nickel-palladium-gold, nickel-gold, the like, or a combination thereof, and may be formed by plating.

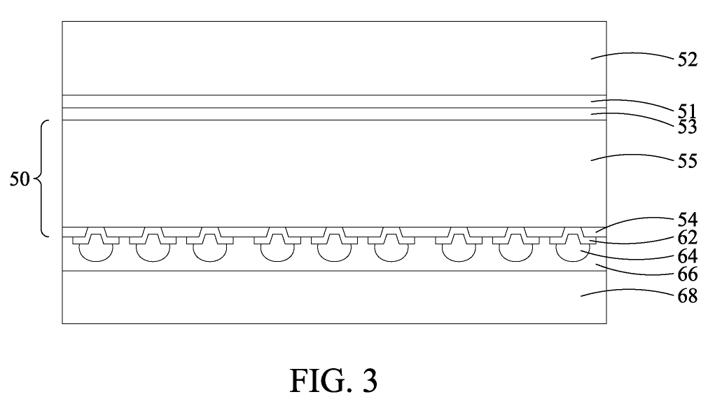

In FIG. 3, the first integrated circuit package structure 70 is attached to a carrier 68 by an adhesive 66. The carrier 68 may be a semiconductor carrier, a glass carrier, a ceramic carrier, or the like. The adhesive 66 may be between the isolation layer 54 and the carrier 68, and may cover surfaces of the UBMs 62 and the electrical connectors 64. The adhesive 66 may separate the electrical connectors 64 from the carrier 68. The first integrated circuit package structure 70 may be attached to the carrier 68 by applying the adhesive 66 on the carrier 68, placing the first integrated circuit package structure 70 on the carrier 68, and curing the adhesive 66.

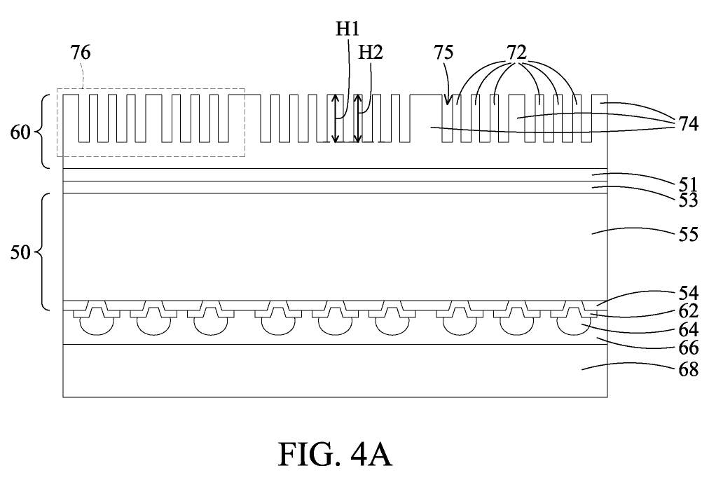

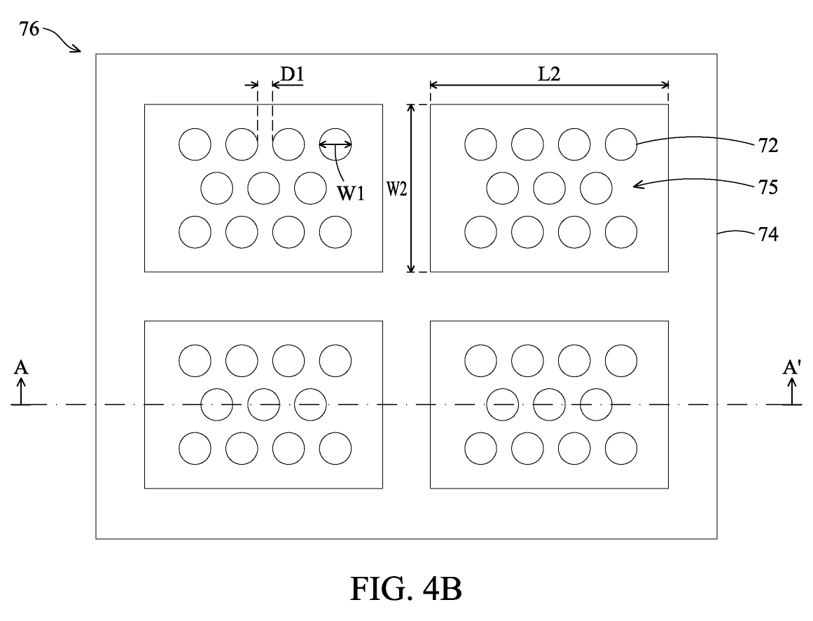

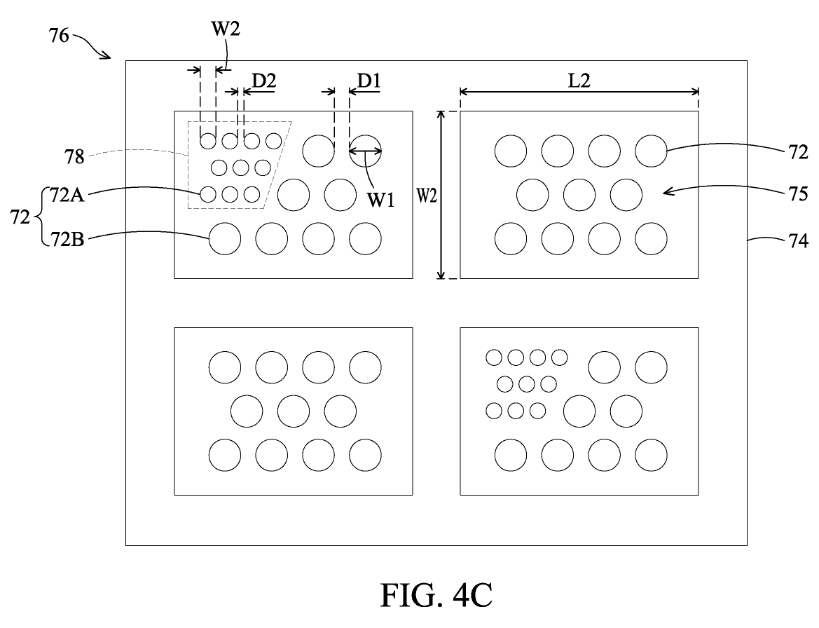

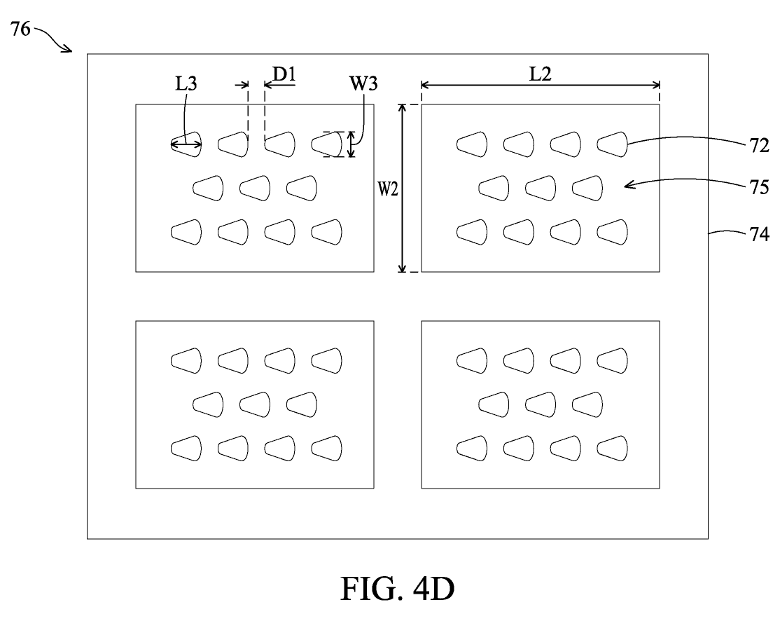

In FIG. 4A, the material layer 52 is patterned to form a cooling system base layer 60. The cooling system base layer 60 may comprise raised portions 74, recesses 75 between raised portions 74, and pins 72 protruding from bottoms of the recesses 75. The pins 72 and the raised portions 74 may comprise the same material as the material layer 52. The patterning may be done by suitable photolithography and etching processes, such as forming a mask, performing an anisotropic etching, and removing the mask. The anisotropic etching may be a dry etching, such as deep reactive-ion etching (DRIE), or the like. The etchant of the anisotropic etching may be fluorine or the like. The raised portions 74 may have a first height H1 in a range between about 50 µm to about 300 µm. The pins may have a second height H2 in a range between about 50 µm to about 300 µm. In some embodiments, the first height H1 is equal to the second height H2.

FIG. 4B shows a top-down view of a region 76 shown in FIG. 4A. The cross-sectional view shown in FIG. 4A may be obtained along a reference cross-section A-A’ in the top-down view shown in FIG. 4B, wherein like numerals refer to like features formed by like processes. The top-down view of the region 76 may correspond to a top-down view of a subsequently formed cooling system base component over the subsequently formed integrated circuit die component, as described in greater details below. As shown in FIG. 4B, the raised portions 74 may divide the region 76 into one or more enclosed compartments, which correspond to one or more recesses 75. Each recess 75 and the pins 72 protruding from the bottom of the recess 75 are encircled by the raised portions 74. The raised portions 74 may confine the liquid coolant within each enclosed compartment while heat may be transferred from the pins 72 as well as the raised portions 74 to the liquid coolant during the operation of the subsequently formed cooling system, as described in greater details below. FIG. 4B shows four enclosed compartments in the region 76 as an example, and the region 76 may have other numbers of enclosed compartments.

In the embodiments shown in FIG. 4B, the pins 72 within each enclosed compartment (e.g., the recess 75) form a staggered array with a same pitch D1 between adjacent pins 72, top surfaces of the pins 72 have a same shape and a same size, and the enclosed compartments have a same shape and a same size. The pitch D1 may be in a range between about 100 µm and about 500 µm. The top surfaces of the pins 72 may have a shape of a circle with a width W1 (e.g., diameter) in a range between about 100 µm and about 500 µm. The enclosed compartments may have a shape of a rectangle with a length L2 in a range between about 5 mm and about 15 mm, and a width W2 in a range between about 5 mm and about 15 mm. In other embodiments, the pins 72 may form a different pattern, the top surfaces of the pins 72 may have other shapes and sizes, and the enclosed compartments may have other shapes and sizes.

FIG. 4C shows a top-down view of the region 76 similar to the one shown in FIG. 4B in accordance with some embodiments, wherein like numerals refer to like features formed by like processes. In some enclosed compartments (e.g., the recesses 75) of the region 76, the pins 72 may be spaced apart by different pitches and the top surfaces of the pins 72 may have different sizes. The pins 72A in regions (e.g., region 78) that may be over thermal hotspots of the subsequently formed integrated circuit die components may be spaced apart by a smaller pitch and have top surfaces with smaller widths than the pins 72B within a same enclosed compartment, which may lead to more effective cooling of the subsequently formed integrated circuit die components, as described in greater details below. In the embodiments shown in FIG. 4C, the pins 72A in the region 78 near a corner of the enclosed compartment are spaced apart by a pitch D2 and have top surfaces with a width W2, while the pins 72B within the same enclosed compartment are spaced apart by the pitch D1 larger than the pitch D2 and have top surfaces with the width W1 larger than the width W2.

FIG. 4D shows a top-down view of the region 76 similar to the one shown in FIG. 4B in accordance with some embodiments, wherein like numerals refer to like features formed by like processes. In the embodiments shown in FIG. 4D, the pins 72 within each enclosed compartment (e.g., the recess 75) form a staggered array with the same pitch D1 between adjacent pins 72, and the top surfaces of the pins 72 have a same shape and a same size. The top surfaces of the pins 72 have a shape of a pear (or a water drop). The pear has a narrow end and a broad end. A length L3 from the narrow end to the broad end may be in a range between about 100 µm and 500 µm. A width W3 of the broad end may be in a range between about 100 µm and 500 µm. When the top surfaces of the pins 72 have the shape of a pear, the fluid dynamics (e.g., speed) of the liquid coolant may be improved as the liquid coolant flows in a direction that is from the broad end to the narrow end, which may lead to turbulent flow of the liquid coolant. As a result, more effective cooling of the subsequently formed integrated circuit die components may be achieved, as described in greater details below.

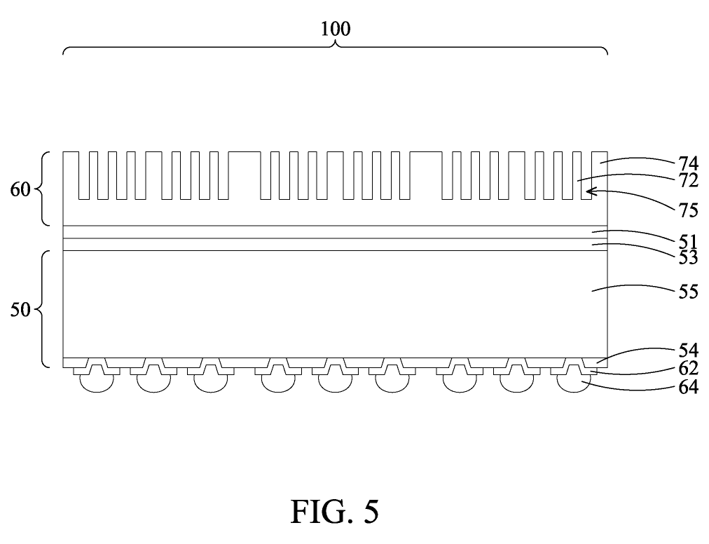

In FIG. 5, the carrier 68 and the adhesive 66 (shown in FIG. 4A) are removed. The adhesive 66 may be removed by dissolving the adhesive 66 with a suitable solvent. After removing the adhesive 66, the carrier 68 may be removed and the electrical connectors 64 may be exposed. The structure shown in FIG. 5 may be referred to as a second integrated circuit package structure 100.

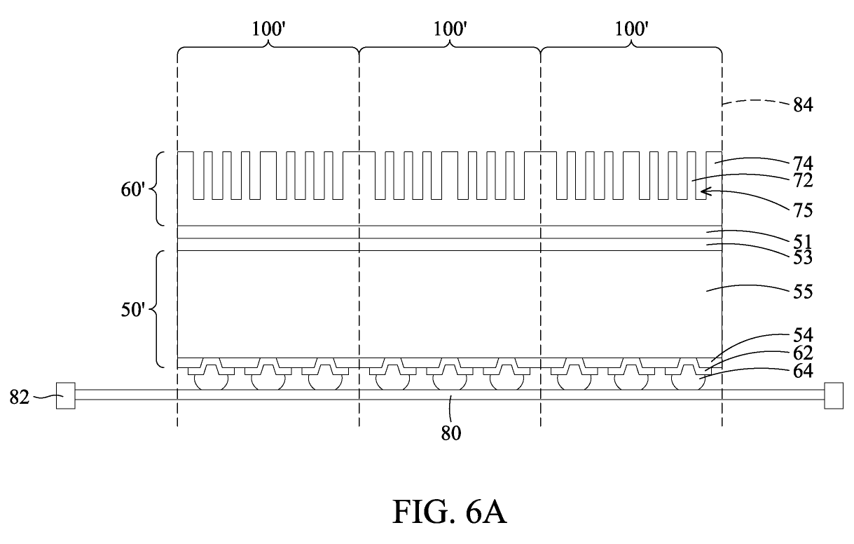

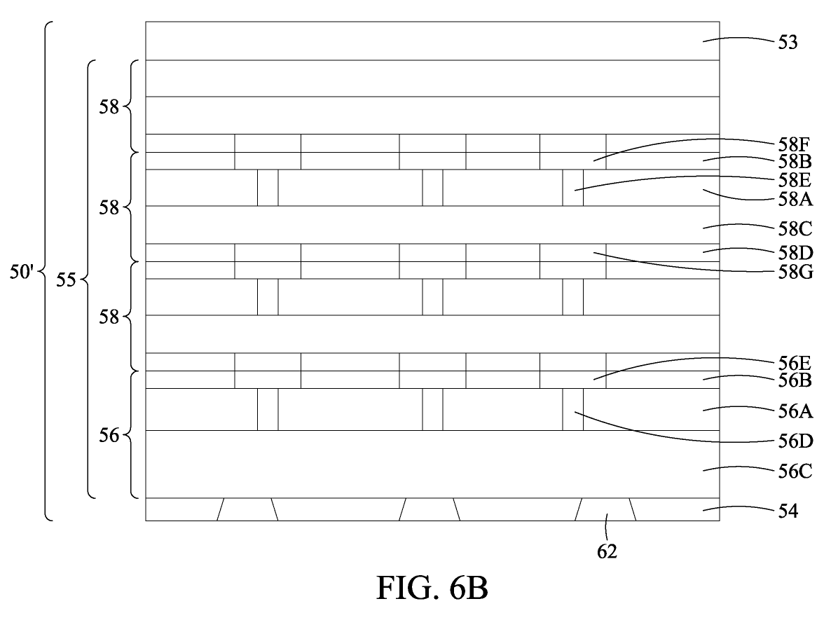

In FIG. 6A, the second integrated circuit package structure 100 is singulated to form individual integrated circuit package components 100’. The second integrated circuit package structure 100 may be placed on a tape 80 supported by a frame 82. Then the second integrated circuit package structure 100 may be singulated along scribe lines 84, so that the second integrated circuit package structure 100 may be separated into individual integrated circuit package components 100’. At the same time, the integrated circuit die layer 50 may be separated into individual integrated circuit die components 50’, and the cooling system base layer 60 may be separated into individual cooling system base components 60’. Each integrated circuit package component 100’ may comprise a cooling system base component 60’ over an integrated circuit die component 50’. The top-down view of each integrated circuit package component 100’ may be same or similar to the ones shown in FIGS. 4B, 4C, and 4D. The singulation process may include a sawing process, a laser cutting process, or the like. A cleaning process or rinsing process may be performed after the singulation process.

Each integrated circuit die component 50’ may comprise the integrated circuit die or the stack of integrated circuit dies (not separately illustrated). The integrated circuit die may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like.

The integrated circuit die may comprise a semiconductor substrate, such as silicon, doped or undoped, or an active layer of a semiconductor-on-insulator (SOI) substrate. The semiconductor substrate may c0mprise other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, and/or GaInAsP, or combinations thereof. Other substrates, such as multi-layered or gradient substrates, may also be used. The integrated circuit die may comprise the devices on an active surface of the semiconductor substrate. The devices may be active devices (e.g., transistors, diodes, etc.), capacitors, resistors, or the like.

The integrated circuit die may also comprise an interconnect structure on the active surface of the semiconductor substrate. The interconnect structure may interconnect the devices to form an integrated circuit. The interconnect structure may comprise metallization patterns in dielectric layers. The dielectric layers may be low-k dielectric layers. The metallization patterns may include metal lines and vias, which may be formed in the dielectric layers by a damascene process, such as a single damascene process, a dual damascene process, or the like. The metallization patterns may be formed of a suitable conductive material, such as copper, tungsten, aluminum, silver, gold, a combination thereof, or the like. The metallization patterns may be electrically coupled to the devices. Conductive vias may be disposed in the semiconductor substrate. The conductive vias may be electrically coupled to the metallization patterns of the interconnect structure.

FIG. 6B illustrates an example of the composition of the integrated circuit die component 50’, where the integrated circuit die component 50’ comprises the stack of integrated circuit dies including a logic die 56 (e.g., CPU, GPU, SoC, AP, microcontroller) and a stack of memory dies 58 (e.g., DRAM, SRAM) in the device layer 55. The stack of memory dies 58 may be referred to as a high bandwidth memory (HBM) stack. The logic die 56 may be on the bottom of the device layer 55. The logic die 56 may comprise a substrate 56A, a bonding layer 56B on a first side of the substrate 56A, and an interconnect structure 56C on a second side of the substrate 56A. The interconnect structure 56C may be in contact with the isolation layer 54. Conductive vias 56D may extend through the substrate 56A and electrically couple to the metallization patterns (not shown) of the interconnect structure 56C and conductive pads 56E in the bonding layer 56B. The metallization patterns of the interconnect structure 56C may be electrically coupled to the UBMs 62.

The stack of memory dies 58 may be on the bonding layer 56B of the logic die 56. Some of the stack of memory dies 58 may comprise a substrate 58A, a top bonding layer 58B on a first side of the substrate 58A, an interconnect structure 58C on a second side of the substrate 58A, and a bottom bonding layer 58D on the interconnect structure 58C. Conductive vias 58E may extend through the substrate 58A and electrically couple to the metallization patterns (not shown) of the interconnect structure 58C and top conductive pads 58F in the top bonding layer 58B. The metallization patterns of the interconnect structure 58C may be electrically coupled to bottom conductive pads 58G in the bottom bonding layer 58D. The memory die 58 at the top of the stack of memory dies 58 may comprise a substrate 58A, an interconnect structure 58C on a second side of the substrate 58A, and a bottom bonding layer 58D on the interconnect structure 58C. The metallization patterns (not shown) of the interconnect structure 58C may be electrically coupled to bottom conductive pads 58G in the bottom bonding layer 58D. A first side of the substrate 58A may be in contact with the second bonding layer 53.

The bonding layer 56B, the top bonding layer 58B, and the bottom bonding layer 58D may comprise a dielectric material, such as silicon oxide, silicon nitride, or the like. The conductive pads 56E, the top conductive pads 58F, and the bottom conductive pads 58G may comprise a metal, such as copper, aluminum, or the like. The logic die 56 and the memory die 58 at the bottom of the stack of memory dies 58 may be bonded together by dielectric-to-dielectric bonding and metal-to-metal bonding, wherein the bonding layer 56B may be bonded to the bottom bonding layer 58D by dielectric-to-dielectric bonding, and the conductive pads 56E may be bonded to the bottom conductive pads 58G by metal-to-metal bonding. The neighboring memory dies 58 may be bonded together by dielectric-to-dielectric bonding and metal-to-metal bonding, wherein the top bonding layer 58B may be bonded to the neighboring bottom bonding layer 58D by dielectric-to-dielectric bonding, and the top conductive pads 58F may be bonded to the neighboring bottom conductive pads 58G by metal-to-metal bonding. As a result, the logic die 56 and each of the stack of memory dies 58 may be electrically coupled to one another.

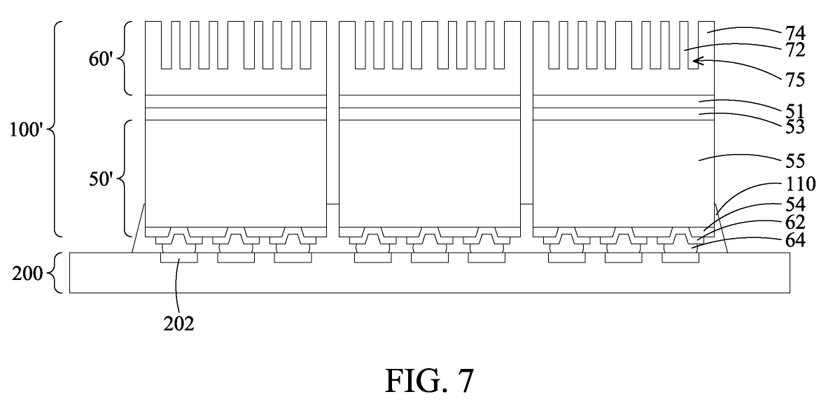

In FIG. 7, the integrated circuit package components 100’ are bonded to a package substrate 200 and an underfill 110 is formed between the integrated circuit package components 100’ and the package substrate 200. The package substrate 200 may comprise conductive pads 202. In some embodiments, the package substrate 200 comprise materials such as fiberglass reinforced resin, bismaleimide-triazine (BT) resin, other printed circuit board (PCB) materials, or the like. In some embodiments, the package substrate 200 comprise materials such as silicon, germanium, silicon germanium, silicon carbide, gallium arsenic, indium arsenide, indium phosphide, silicon germanium carbide, gallium arsenic phosphide, gallium indium phosphide, or the like.

The package substrate 200 may include active and/or passive devices (not separately illustrated), such as transistors, capacitors, resistors, combinations thereof, or the like. The active and/or passive devices may be formed using any suitable methods. The package substrate 200 may comprise metallization layers (not separately illustrated) physically and electrically coupled to the conductive pads 202. The metallization layers may be formed over the active and passive devices and may connect the active and/or passive devices to form functional circuitry. The metallization layers may be alternating layers of dielectric material (e.g., low-k dielectric material) and conductive material (e.g., copper) with conductive vias interconnecting the layers of conductive material. In some embodiments, the package substrate 200 is free of active and passive devices.

During the bonding process the electrical connectors 64 may be reflowed to bond the integrated circuit package components 100’ to the conductive pads 202. The electrical connectors 64 may electrically and physically couple the package substrate 200 to the integrated circuit package components 100’. In some embodiments, a solder resist (not separately illustrated) is formed on the package substrate 200. The electrical connectors 64 may be disposed in openings in the solder resist to electrically and physically couple to the conductive pads 202. The solder resist may be used to protect areas of the package substrate 200 from external damage.

The underfill 110 may surround the electrical connectors 64 and protect the joints resulting from the reflowing of the electrical connectors 64. The underfill 110 may encircle the integrated circuit package components 100’ in the top-down view. The underfill 110 may be formed by a capillary flow process after the integrated circuit package components 100’ is attached or by a suitable deposition method before the integrated circuit package components 100’ is attached. The underfill 110 may be subsequently cured. The layout of the integrated circuit package components 100’ on the package substrate 200 shown in FIG. 7 is an example, and other layouts are contemplated. FIG. 7 shows the integrated circuit package components 100’ on the package substrate 200 with a same height as an example, the integrated circuit package components 100’ on the package substrate 200 may have different heights.

FIGS. 1 through 7 illustrate the integrated circuit die component 50’ as the integrated circuit die or the stack of integrated circuit dies in accordance with some embodiments. In other embodiments, the integrated circuit die component 50’ may be an integrated circuit package comprising the integrated circuit die or the stack of integrated circuit dies. The integrated circuit package may be a system on integrated chips (SoIC) package, an integrated fan-out on substrate (InFO) package, a chip on wafer on substrate (CoWoS) package, or the like.

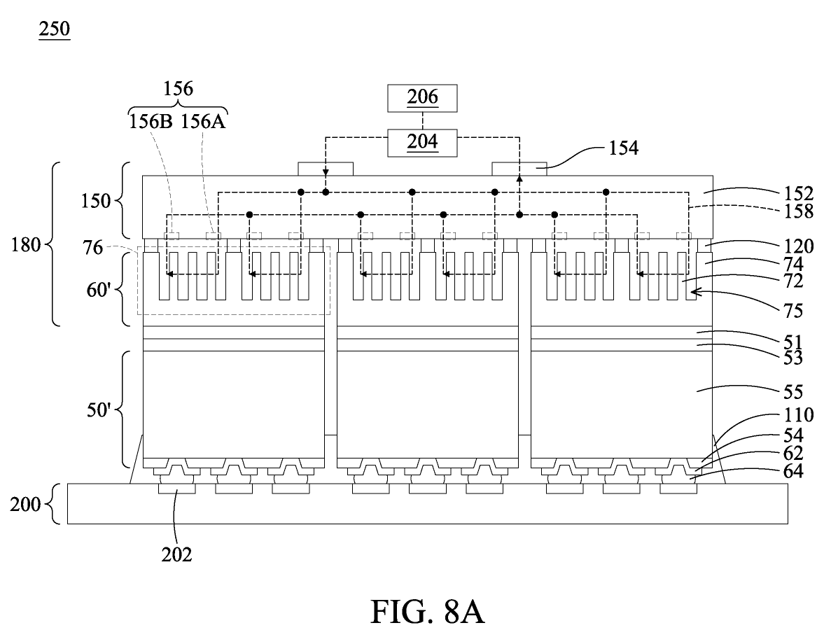

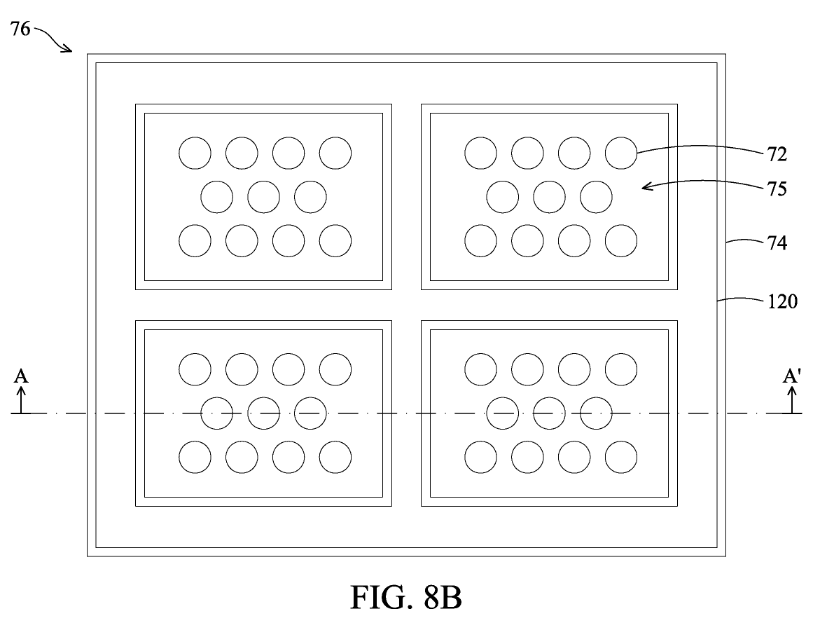

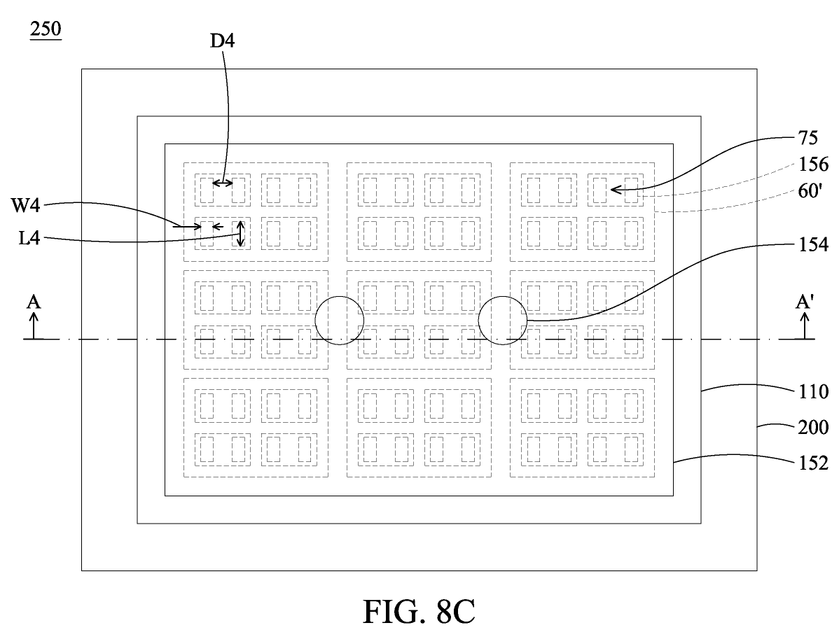

In FIGS. 8A, 8B, and 8C, a cooling system lid component 150 is attached to the cooling system base components 60’ by sealants 120. The cross-sectional view shown in FIG. 8A may be obtained along the reference cross-section A-A’ in the top-down views shown in FIGS. 8B and 8C, wherein like numerals refer to like features formed by like processes. FIG. 8B shows the top-down view of the region 76 shown in FIG. 8A. The cooling system base components 60’ are shown in dashed lines in FIG. 8C for illustrative purposes. The cooling system lid component 150, the sealants 120, and the cooling system base components 60’ may be collectively refer to as a cooling system 180. The structure shown in FIGS. 8A and 8C may be referred to as an integrated circuit package 250. The cooling system 180 may utilize liquid coolant to cool the integrated circuit die components 50’ underneath during the operation of the integrated circuit package 250.

The sealants 120 may be applied to top surfaces of the raised portions 74 of the cooling system base components 60’ before the cooling system lid component 150 is placed on the cooling system base components 60’, wherein the sealants 120 may contact bottom surfaces of the cooling system lid component 150. In some embodiments, the sealants 120 comprise a polymer material and are subsequently cured. In some embodiments, the sealants 120 comprise a metallic material, such as thermal interface material (TIM). The pins 72 may be spaced apart from the cooling system lid component 150 and the top surfaces of the pins 72 may be exposed. FIG. 8A shows the sealants 120 on the cooling system base components 60’ with a same height as an example, the sealants 120 on the cooling system base components 60’ may have different heights when the cooling system base components 60’ have different heights, so that one cooling system lid component 150 may be used to form the cooling system 180 with the cooling system base components 60’ with different heights.

The cooling system lid component 150 may comprise a body 152 and adaptors 154. The body 152 may comprise a coolant distribution network 158 and openings 156. FIG. 8A shows examples of flow paths of the liquid coolant in dashed lines with arrows to illustrate an embodiment of the coolant distribution network 158. The openings 156 are shown in dashed lines in FIGS. 8A and 8C for illustrative purposes. The adaptors 154 may be connected to an external inlet and an external outlet for the liquid coolant to flow into and out of the cooling system 180, respectively. A pumping system 204 may be connected to the cooling system 180 through the adaptors 154. The pumping system 204 may move the liquid coolant from a reservoir 206 into the cooling system 180 and move the liquid coolant from the cooling system 180 into the reservoir 206. The openings 156 may face the recesses 75 and the pins 72 of the cooling system base components 60’, and the openings 156 may comprise inlets 156A and outlets 156B for the liquid coolant to flow into and out of the enclosed compartments (e.g., the recesses 75) of the cooling system base components 60’, respectively. The coolant distribution network 158 may be connected to the adaptors 154 and the openings 156, and may direct the transportation of the liquid coolant in the cooling system 180.

The sealants 120 may extend between the top surfaces of the raised portions 74 of the cooling system base components 60’ and bottom surfaces of the cooling system lid component 150. The sealants 120 may seal a portion of the cooling system lid component 150 to the corresponding enclosed compartment of the cooling system base components 60’ underneath, which may confine the liquid coolant with the enclosed compartment. One or more sealed enclosed compartments may be in each cooling system base components 60’ over the corresponding integrated circuit die component 50’. When multiple sealed enclosed compartments are disposed over the corresponding integrated circuit die component 50’, the integrated circuit die component 50’ may be more effectively cooled during the operation of the integrated circuit package 250.

The cooling system lid component 150 may be formed of copper, stainless steel, polymer, or the like. In the embodiments illustrated in FIG. 8C, the openings 156 have a same shape and a same size. The openings 156 may have a shape of a rectangle with a length L4 in a range between about 5 mm to about 15 mm and a width W4 in a range between about 1 mm to about 2 mm. Two openings 156, which may be a pair of the inlet and the outlet, are disposed over opposite sides of each enclosed compartment (e.g., the recess 75). The two openings 156 may be spaced apart by a distance D4 in a range between about 3 mm to about 11 mm. The layout of the openings 156 in the cooling system lid component 150 shown in FIG. 8C is an example, and other layouts are contemplated. The sealants 120 may be formed of epoxy, silicone, or the like. The liquid coolant may be deionized water, a glycol based coolant, or the like.

As an example of the working principle of the cooling system 180 during the operation of the integrated circuit package 250, the liquid coolant may flow into the cooling system 180 through one adaptor 154 (e.g., inlet) and be distributed by the coolant distribution network 158 to the inlet 156A disposed over each enclosed compartment. The liquid coolant may enter and flow across the enclosed compartment while contacting the corresponding pins 72 as well as the corresponding raised portions 74 of the corresponding cooling system base component 60’. At the same time, the heat being generated in the integrated circuit die component 50’ underneath the cooling system base component 60’ may be transferred to the cooling system base component 60’ through the first bonding layer 51 and the second bonding layer 53. The heat may be further transferred to the liquid coolant when the liquid coolant contacts the pins 72 as well as the raised portions 74. Then the liquid coolant may exit each enclosed compartment through the outlet 156B disposed over the enclosed compartment, and may be directed to another adaptor 154 (e.g., outlet) by the coolant distribution network 158 to flow out of the cooling system 180. As a result, the integrated circuit die components 50’ may be effectively cooled during the operation of the integrated circuit package 250.

The embodiments may have some advantageous features. By forming the cooling system 180 over the integrated circuit die components 50’, the heat generated by the integrated circuit die components 50’ may be effectively transferred to the liquid coolant flowing through the cooling system 180. As a result, the integrated circuit die components 50’ may be effectively cooled during the operation of the integrated circuit package 250, thereby improving the performance and reliability of the integrated circuit package 250.

In an embodiment, a semiconductor package includes a substrate; a first package component bonded to the substrate, the first package component including a first semiconductor die; and a first cooling system over the first package component, the first cooling system including a first base over the first package component, wherein the first base includes a first recess, a first pin protruding from a bottom of the first recess, and a first raised portion encircling the recess in a top-down view; a lid over the first base, wherein the lid is spaced apart from the first pin; and a sealant connecting the lid to the first raised portion of the first base. In an embodiment, the first raised portion and the first pin of the first base include a same first material. In an embodiment, the first material is silicon. In an embodiment, the first package component further includes a second semiconductor die stacked on the first semiconductor die, and wherein the first semiconductor die is a logic die and the second semiconductor die is a memory die. In an embodiment, the semiconductor package further includes a first dielectric bonding layer and a second dielectric bonding layer between the first package component and the first base. In an embodiment, the first base further includes a second pin, a third pin, and a fourth pin protruding from the bottom of the first recess, wherein the first pin, the second pin, the third pin, and the fourth pin are of a same size in a top-down view, and wherein the first pin, the second pin, the third pin, and the fourth pin are arranged in a staggered array in the top-down view. In an embodiment, the first base further includes a second pin, a third pin, and a fourth pin protruding from the bottom of the first recess, wherein the first pin and the second pin are larger than the third pin and the fourth pin in a top-down view. In an embodiment, the first pin is spaced apart from the second pin by a first distance and the third pin is spaced apart from the fourth pin by a second distance, and wherein the first distance is larger than the second distance.

In an embodiment, a semiconductor package includes a substrate; a first package component bonded to the substrate, the first package component including two or more semiconductor dies stacked vertically; and a first cooling system over the first package component, the first cooling system including a first base bonded to the first package component, wherein the first base includes a first recess and a first pin protruding from a bottom of the first recess, a second recess and a second pin protruding from a bottom of the second recess, and a first raised portion between the first recess and the second recess; and a lid attached to the first base. In an embodiment, top surfaces of the first pin and the second pin of the first base are exposed and a top surface of the first raised portion of the first base are in contact with a sealant on a bottom surface of the lid. In an embodiment, the first base includes a semiconductor material. In an embodiment, the semiconductor package further includes an underfill between the first package component and the substrate, wherein the underfill encircles the first package component in a top-down view. In an embodiment, the lid includes a coolant distribution network. In an embodiment, the lid includes a first coolant inlet and a first coolant outlet facing the first recess of the first base, and wherein the lid further includes a second coolant inlet and a second coolant outlet facing the second recess of the first base.

In an embodiment, a method of manufacturing a semiconductor package includes: bonding a material layer to a package component layer; removing a portion of the material layer to form a base layer, wherein the base layer include a first recess, a first plurality of pins protruding from a bottom of the first recess, and a first raised portion encircling the first recess in a top-down view; singulating the base layer and the package component layer to form a first base and a first package component, wherein the first base remains bonded to the first package component, and wherein the first base includes the first recess, the first plurality of pins, and the first raised portion; bonding the first package component to a substrate; and attaching a lid to the first raised portion of the first base by a sealant, wherein the lid includes first openings facing the first base. In an embodiment, the material layer includes a semiconductor material. In an embodiment, top surfaces of first plurality of pins of the first base are separated from the lid. In an embodiment, the first package component includes a stack of memory dies on a logic die. In an embodiment, bonding the material layer to the package component layer further includes bonding a first bonding layer on the material layer to a second bonding layer on the package component layer by dielectric-to-dielectric bonding. In an embodiment, the method further includes singulating the base layer and the package component layer to form a second base and a second package component, wherein the second base remains bonded to the second package component, and wherein the second base includes a second recess, a second plurality of pins protruding from a bottom of the second recess, and a second raised portion encircling the second recess in a top-down view; bonding the second package component to the substrate beside the first package component; and attaching the lid to the second raised portion of the second base by the sealant, wherein the lid includes second openings facing the second base.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor package, the method comprising:
bonding a material layer to a package component layer;
removing a portion of the material layer to form a base layer, wherein the base layer comprise a first recess, a first plurality of pins protruding from a bottom of the first recess, and a first raised portion encircling the first recess in a top-down view;
singulating the base layer and the package component layer to form a first base and a first package component, wherein the first base remains bonded to the first package component, and wherein the first base comprises the first recess, the first plurality of pins, and the first raised portion;
bonding the first package component to a substrate; and
attaching a lid to the first raised portion of the first base by a sealant, wherein the lid comprises first openings facing the first base.

2. The method of claim 1, wherein the material layer comprises a semiconductor material.

3. The method of claim 1, wherein top surfaces of first plurality of pins of the first base are separated from the lid.

4. The method of claim 1, wherein the first package component comprises a stack of memory dies on a logic die.

5. The method of claim 1, wherein bonding the material layer to the package component layer further comprises bonding a first bonding layer on the material layer to a second bonding layer on the package component layer by dielectric-to-dielectric bonding.

6. The method of claim 1, further comprising:
singulating the base layer and the package component layer to form a second base and a second package component, wherein the second base remains bonded to the second package component, and wherein the second base comprises a second recess, a second plurality of pins protruding from a bottom of the second recess, and a second raised portion encircling the second recess in the top-down view;
bonding the second package component to the substrate beside the first package component; and
attaching the lid to the second raised portion of the second base by the sealant, wherein the lid comprises second openings facing the second base.

7. A method of manufacturing a semiconductor package, the method comprising:
bonding a material layer to a device layer layer by dielectric-to-dielectric bonding;
patterning the material layer to form a first plurality of pins and a first barrier encircling the first plurality of pins in a top-down view;
dicing the material layer and the device layer to form a cooling system bottom component and a package component, wherein the cooling system bottom component and the package component are bonded by dielectric-to-dielectric bonding, and wherein the cooling system bottom component comprises the first plurality of pins and the first barrier;
bonding the package component to a substrate; and
attaching a cooling system top component to the cooling system bottom component by a sealant.

8. The method of claim 7, wherein the first plurality of pins has a shape of a pear in the top-down view.

9. The method of claim 7, wherein the first plurality of pins is arranged in a staggered array in the top-down view.

10. The method of claim 7, wherein the material layer is a single material layer comprising silicon, silicon carbide, or diamond.

11. The method of claim 7, wherein the cooling system top component comprises a first opening and a second opening facing the first plurality of pins.

12. The method of claim 7, wherein the cooling system top component is attached to the first barrier of the cooling system bottom component by a sealant.

13. The method of claim 7, wherein top surfaces of the first plurality of pins are exposed after attaching the cooling system top component to the cooling system bottom component.

14. A method of manufacturing a semiconductor package, the method comprising:
bonding a first dielectric bonding layer on a material layer to a second dielectric bonding layer on an active device layer;
patterning the material layer to form a first pin, a second pin, and a barrier surrounding the first pin and the second pin in a top-down view;
singulating the material layer and the active device layer to form a package component, wherein the package component comprises an active device component and a cooling system bottom component, and wherein the cooling system bottom component comprises the first pin, the second pin, and the barrier; and
attaching a cooling system top component to the barrier by a sealant, wherein the first pin and the second pin are separated from the cooling system top component.

15. The method of claim 14, wherein the first pin and the second pin have a circular shape in the top-down view.

16. The method of claim 15, wherein a diameter of the first pin is greater than a diameter of the second pin.

17. The method of claim 14, wherein the cooling system top component comprises a coolant distribution network.

18. The method of claim 17, wherein the cooling system top component comprises a coolant inlet and a coolant outlet facing the first pin and the second pin.

19. The method of claim 14, wherein the first pin and the barrier have a same height.

20. The method of claim 14, wherein the material layer is a semiconductor layer comprising silicon.
